(19) United States
(12) Patent Application Publication
(10) Pub. No.: US 2025/0385106 A1
(43) Pub. Date: Dec. 18, 2025

(54) SUBSTRATE CLEANING APPARATUS AND SUBSTRATE TREATING SYSTEM INCLUDING THE SAME

(71) Applicant: SAMSUNG ELECTRONICS CO., LTD., Suwon-si (KR)

(72) Inventors: In Hwa BAEK, Suwon-si (KR); Soon Hyun KIM, Cheonan-si (KR); Hong Goo CHUNG, Cheonan-si (KR); Yong PARK, Cheonan-si (KR); Young Ho KIM, Suwon-si (KR); Ki-Beom LEE, Suwon-si (KR)

(73) Assignees: SAMSUNG ELECTRONICS CO., LTD., Suwon-si (KR); SEMES CO., LTD., Cheonan-si (KR)

(21) Appl. No.: 18/990,403

(22) Filed: Dec. 20, 2024

(30) Foreign Application Priority Data
Jun. 14, 2024 (KR) 10-2024-0077445

(51) Int. Cl. H01L 21/67; A46B 13/00; A46B 13/02; B08B 1/12; B08B 1/20; B08B 1/34; B08B 1/36; B08B 3/04; B08B 3/08; B08B 3/10; B08B 5/00; B08B 13/00; H01L 21/683

(52) U.S. Cl. CPC H01L 21/67046; A46B 13/001; A46B 13/008; A46B 13/02; B08B 1/12; B08B 1/20; B08B 1/34; B08B 1/36; B08B 3/041; B08B 3/08; B08B 3/10; B08B 5/00; B08B 13/00; A46B 2200/3073; H01L 21/6838

(57) ABSTRACT

A substrate cleaning apparatus may be provided and include: a first process chamber configured to plasma-treat a first substrate and a second substrate; a substrate cleaning apparatus configured to clean the first substrate and the second substrate; and a second process chamber configured to bond the first substrate and the second substrate to each other, wherein the substrate cleaning apparatus is further configured to remove, using a cleaning liquid and a brush, a foreign substance adhered to the first substrate and the second substrate, and wherein the second process chamber is further configured to bond the first substrate and the second substrate to each other after the first substrate and the second substrate are cleaned by the substrate cleaning apparatus.

### CROSS-REFERENCE TO RELATED APPLICATION

This application claims priority from Korean Patent Application No. 10-2024-0077445, filed on Jun. 14, 2024, in the Korean Intellectual Property Office, and all the benefits accruing therefrom under 35 U.S.C. 119, the contents of which in its entirety are herein incorporated by reference.

### BACKGROUND

### 1. Field

Embodiments of the present disclosure relate to a substrate cleaning apparatus that may be provided to a facility that produces a semiconductor package or an electronic product, and a substrate treating system including the same.

### 2. Description of Related Art

A substrate used to produce a semiconductor package such as a high bandwidth memory (HBM) may be bonded to another substrate. However, foreign substances may exist on a surface of the substrate due to various factors. Therefore, it is necessary to remove the foreign substances through a cleaning process before bonding the substrate to another substrate.

For the cleaning process, chemical or deionized water (DIW) may be used. However, this method has limitations in removing the foreign substances stuck to the substrate with a strong force.

### SUMMARY

According to embodiments of the present disclosure, a substrate cleaning apparatus that uses a brush to remove foreign substances and a substrate treating system including the same.

According to embodiments of the present disclosure, a substrate cleaning apparatus may be provided and include: a first process chamber configured to plasma-treat a first substrate and a second substrate; a substrate cleaning apparatus configured to clean the first substrate and the second substrate; and a second process chamber configured to bond the first substrate and the second substrate to each other, wherein the substrate cleaning apparatus is further configured to remove, using a cleaning liquid and a brush, a foreign substance adhered to the first substrate and the second substrate, and wherein the second process chamber is further configured to bond the first substrate and the second substrate to each other after the first substrate and the second substrate are cleaned by the substrate cleaning apparatus. According to embodiments of the present disclosure, a substrate cleaning apparatus may be provided and include: a substrate support configured to support a substrate; a first liquid supply configured to provide a first liquid to a first surface of the substrate; a second liquid supply configured to provide a second liquid to a second surface of the substrate; and a foreign substance remover configured to: remove a foreign substance from the second surface by contacting the second surface, wherein the foreign substance remover is further configured to remove the foreign substance using the second liquid and a brush, wherein the foreign substance remover is further configured to rotate while being in contact with the second surface, and wherein the foreign substance remover is further configured to flip or vertically move based on whether cleaning by the substrate cleaning apparatus is in progress.

According to embodiments of the present disclosure, a substrate cleaning apparatus may be provided and include: a first process chamber configured to etch a first substrate and a second substrate; a substrate cleaning apparatus configured to clean the first substrate and the second substrate and to remove, using a cleaning liquid and a brush, a foreign substance adhered to the first substrate and the second substrate; and a second process chamber configured to bond the first substrate and the second substrate to each other, wherein the substrate cleaning apparatus includes: a substrate support configured to support the first substrate; a first liquid supply configured to provide a first liquid to a first surface of the first substrate; a second liquid supply configured to provide a second liquid to a second surface of the first substrate; and a foreign substance remover configured to remove the foreign substance from the second surface by contacting the second surface, wherein the foreign substance remover is further configured to rotate while being in contact with the second surface, wherein the foreign substance remover is further configured to move inwardly or outwardly of the first substrate while being in contact with the second surface, wherein the foreign substance remover is further configured to flip or vertically move based on whether cleaning by the substrate cleaning apparatus is in progress, wherein the foreign substance remover and the second liquid supply are configured to operate simultaneously, and wherein the second process chamber is further configured to bond the first substrate and the second substrate after the first substrate and the second substrate are cleaned by the substrate cleaning apparatus.

Aspects and effects of embodiments of the present disclosure are not limited to the aspects and effects mentioned above, and other aspects and effects of embodiments of the present disclosure not mentioned will be clearly understood by those skilled in the art from the description as set forth below.

### BRIEF DESCRIPTION OF DRAWINGS

The above and other aspects and features of the present disclosure will become more apparent by describing in detail example embodiments thereof with reference to the attached drawings, in which:

FIG. 1 is a first example diagram for illustrating an internal structure of a substrate treating system according to some embodiments of the present disclosure.

FIG. 2 is a second example diagram for illustrating an internal structure of the substrate treating system according to some embodiments of the present disclosure.

FIG. 3 is a third example diagram for illustrating an internal structure of the substrate treating system according to some embodiments of the present disclosure.

FIG. 4 is a fourth example diagram for illustrating an internal structure of the substrate treating system according to some embodiments of the present disclosure.

FIG. 5 is a first example diagram for illustrating an internal structure of a substrate cleaning apparatus according to some embodiments of the present disclosure.

FIG. 6 is a first example diagram for illustrating a substrate support of a substrate cleaning apparatus according to some embodiments of the present disclosure.

FIG. 7 is a second example diagram for illustrating a substrate support of a substrate cleaning apparatus according to some embodiments of the present disclosure.

FIG. 8 is a first example diagram for illustrating a foreign substance remover of a substrate cleaning apparatus according to some embodiments of the present disclosure.

FIG. 9 is a second example diagram for illustrating a foreign substance remover of a substrate cleaning apparatus according to some embodiments of the present disclosure.

FIG. 10 is a third example diagram for illustrating a foreign substance remover of a substrate cleaning apparatus according to some embodiments of the present disclosure.

FIG. 11 is a fourth example diagram for illustrating a foreign substance remover of a substrate cleaning apparatus according to some embodiments of the present disclosure.

FIG. 12 is a fifth example diagram for illustrating a foreign substance remover of a substrate cleaning apparatus according to some embodiments of the present disclosure.

FIG. 13 is a sixth example diagram for illustrating a foreign substance remover of a substrate cleaning apparatus according to some embodiments of the present disclosure.

FIG. 14 is a seventh example diagram for illustrating a foreign substance remover of a substrate cleaning apparatus according to some embodiments of the present disclosure.

FIG. 15 is an eighth example diagram for illustrating a foreign substance remover of a substrate cleaning apparatus according to some embodiments of the present disclosure.

FIG. 16 is a ninth example diagram for illustrating a foreign substance remover of a substrate cleaning apparatus according to some embodiments of the present disclosure.

FIG. 17 is a tenth example diagram for illustrating a foreign substance remover of a substrate cleaning apparatus according to some embodiments of the present disclosure.

FIG. 18 is an eleventh example diagram for illustrating a foreign substance remover of a substrate cleaning apparatus according to some embodiments of the present disclosure.

FIG. 19 is a second example diagram for illustrating the internal structure of a substrate cleaning apparatus according to some embodiments of the present disclosure.

FIG. 20 is a third example diagram for illustrating an internal structure of a substrate cleaning apparatus according to some embodiments of the present disclosure.

FIG. 21 is a fourth example diagram for illustrating an internal structure of a substrate cleaning apparatus according to some embodiments of the present disclosure.

FIG. 22 is a first example diagram for illustrating a liquid supply of a substrate cleaning apparatus according to some embodiments of the present disclosure.

FIG. 23 is a second example diagram for illustrating a liquid supply of a substrate cleaning apparatus according to some embodiments of the present disclosure.

FIG. 24 is a fifth example diagram for illustrating an internal structure of a substrate cleaning apparatus according to some embodiments of the present disclosure.

### DETAILED DESCRIPTION

Non-limiting example embodiments of the present disclosure will hereinafter be described with reference to the accompanying drawings. The same reference numerals are used for identical components in the drawings, and redundant explanations for these components may be omitted.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

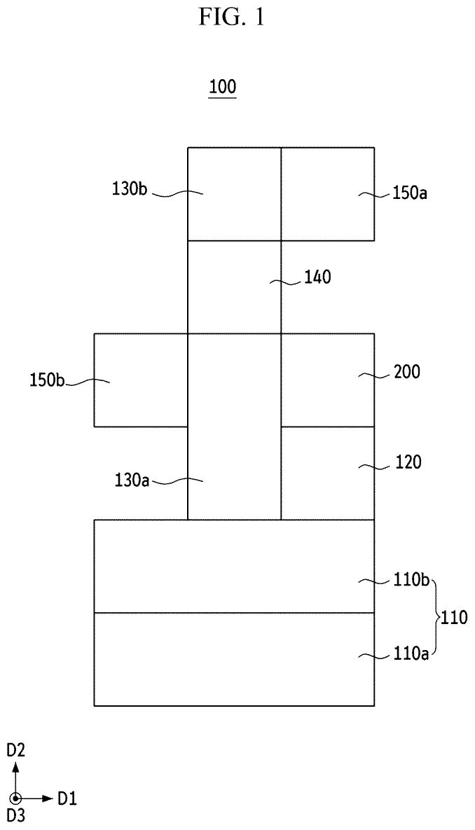

FIG. 1 is a first example diagram for illustrating an internal structure of a substrate treating system according to some embodiments of the present disclosure. According to FIG. 1, a substrate treating system 100 may include a load port module 110a, an index module 110b, a buffer chamber 120, a first transfer module 130a, a second transfer module 130b, a load lock chamber 140, a first process chamber 150a, a second process chamber 150b, and a substrate cleaning apparatus 200.

A first direction D1 and a second direction D2 may define a two-dimensional plane. The first direction D1 may be an X-axis direction, and the second direction D2 may be a Y-axis direction. The first direction D1 may be a left-right direction, and the second direction D2 may be a front-back direction. Alternatively, the first direction D1 may be a front-to-back direction, and the second direction D2 may be a left-right direction. A third direction D3 together with the first direction D1 and the second direction D2 may define a three-dimensional structure. The third direction D3 may be a direction perpendicular to the plane defined by the first direction D1 and the second direction D2. The third direction D3 may be a Z-axis direction. The third direction D3 may be a vertical direction.

The substrate treating system 100 may bond a first substrate and a second substrate to each other. Each of the first substrate and the second substrate may be a wafer. The substrate treating system 100 may perform plasma treatment on the first and second substrates before bonding the first and second substrates to each other. The substrate treating system 100 may clean the first and second substrates before bonding the first and second substrates to each other. The substrate treating system 100 may be provided as a substrate bonding facility.

The substrate treating system 100 may include the substrate cleaning apparatus 200. The substrate cleaning apparatus 200 may clean the first and second substrates after plasma-treating the first and second substrates. The substrate cleaning apparatus 200 may be a process chamber within the substrate treating system 100. A more detailed description of the substrate cleaning apparatus 200 will be set forth later.

The load port module 110a may be configured so that a container may be seated therein. The container may accommodate therein a plurality of substrates. For example, the container may be a front opening unified pod (FOUP). The container may be loaded or unloaded into or from the load port module 110a. Further, the substrate stored in the container may be loaded or unloaded into or from the load port module 110a.

A plurality of containers may be seated in the load port module 110a. The plurality of containers may contain therein objects of a same type. For example, each of a first container, a second container, and a third container may contain a wafer. However, embodiments of the present disclosure are not limited thereto, and the containers may contain therein different types of objects from each other. For example, the first container may contain a wafer, the second container may contain a wafer-type sensor, and the third container may contain a consumable part such as a focus ring. Alternatively, some containers among the plurality of containers may contain therein the same type of products, and the other containers thereof may contain different types of products.

The index module 110b may be disposed at a rear of the load port module 110a. The index module 110b may be provided as an interface so that a substrate may be transferred between the load port module 110a and the buffer chamber 120. According to embodiments, the index module 110b may include a transfer robot for loading and unloading the substrate. The transfer robot may load and unload the substrate in an atmospheric pressure environment. The load port module 110a and the index module 110b may constitute an equipment front end module (EFEM) 110.

The buffer chamber 120 may store a substrate therein. The buffer chamber 120 may temporarily store an untreated substrate therein before transferring the untreated substrate to the load lock chamber 140. The buffer chamber 120 may temporarily store a treated substrate therein before transferring the treated substrate to the container in the load port module 110a.

The buffer chamber 120 may be disposed at a rear of the index module 110b. The transfer robot disposed within the index module 110b may load or unload the substrate into or out of the buffer chamber 120. The buffer chamber 120 may be adjacent to the first transfer module 130a. A transfer robot disposed within the first transfer module 130a may load or unload the substrate into or out of the buffer chamber 120.

The first transfer module 130a may be provided as an interface for transferring the substrate between the buffer chamber 120 and the load lock chamber 140. The first transfer module 130a may be provided as an interface for transferring the substrate between the load lock chamber 140 and the substrate cleaning apparatus 200. The first transfer module 130a may be provided as an interface for transferring the substrate between the substrate cleaning apparatus 200 and the second process chamber 150b. The first transfer module 130a may be surrounded by the buffer chamber 120, the load lock chamber 140, the second process chamber 150b, the substrate cleaning apparatus 200, etc.

Like the index module 110b, the first transfer module 130a may include a transfer robot for loading or unloading the substrate. The transfer robot disposed within the index module 110b and the transfer robot disposed within the first transfer module 130a may load or unload the substrate in the same environment. The transfer robot disposed within the first transfer module 130a may load or unload the substrate in an atmospheric pressure environment.

The load lock chamber 140 may store the substrate therein. The load lock chamber 140 may temporarily store the untreated substrate and the treated substrate therein while being disposed between the first transfer module 130a and the second transfer module 130b. According to embodiments, the load lock chamber 140 may include a buffer stage for temporarily storing the substrate therein.

A plurality of buffer stages may be provided within the load lock chamber 140. For example, a first buffer stage and a second buffer stage may be provided in the load lock chamber 140. The first buffer stage may store an untreated substrate therein, and the second buffer stage may store a treated substrate therein. However, embodiments of the present disclosure are not limited thereto, and each of the first buffer stage and the second buffer stage may also store the substrate therein regardless of whether the substrate has been treated. Each of the first buffer stage and the second buffer stage may store a single substrate or store a plurality of substrates therein.

The second transfer module 130b may be provided as an interface for transferring the substrate between the load lock chamber 140 and the first process chamber 150a. Like the first transfer module 130a, the second transfer module 130b may include a transfer robot for loading and unloading the substrate. The transfer robot disposed within the first transfer module 130a and the transfer robot disposed within the second transfer module 130b may load or unload the substrate in different environments from each other. The transfer robot disposed within the second transfer module 130b may load or unload the substrate in a vacuum environment.

The first process chamber 150a may perform plasma treatment on the substrate. The first process chamber 150a may form a dangling bond on a surface of the substrate. First, a process gas may be supplied into the chamber and the process gas may be excited in a vacuum atmosphere such that the process gas may be converted into plasma to generate ions and active species. When the ions and active species are then irradiated to the surface of the substrate, the surface of the substrate may be modified such that the dangling bonds may be formed.

The first process chamber 150a may treat a substrate using inductively coupled plasma (ICP). However, embodiments of the present disclosure are not limited thereto, and the first process chamber 150a may treat the substrate using capacitively coupled plasma (CCP). Alternatively, the first process chamber 150a may treat the substrate using microwave plasma.

The substrate cleaning apparatus 200 may treat the substrate provided after the first process chamber 150a has treated the substrate. The substrate cleaning apparatus 200 may clean the substrate. The substrate cleaning apparatus 200 may treat the substrate using a wet method. The substrate cleaning apparatus 200 may treat the substrate using chemicals, deionized water (DIW), etc. The substrate cleaning apparatus 200 not only clean the surface of the substrate, but also allow-OH groups, water molecules, etc., to bond well to the surface of the substrate, thereby making bonding between the substrates easier.

The second process chamber 150b may bond the first substrate and the second substrate to each other. The first substrate may be a substrate treated by the first process chamber 150a and the substrate cleaning apparatus 200. The second substrate may be a substrate treated by the first process chamber 150a and the substrate cleaning apparatus 200. For example, the first substrate may be a substrate on which circuits for an image sensor chip are formed, and the second substrate may be a substrate on which light-receiving sensors for the image sensor chip are formed. Alternatively, the first substrate may be a substrate on which circuits for a semiconductor package such as an HBM are formed, and the second substrate may be a substrate on which memories for a semiconductor package are formed.

According to embodiments, the second process chamber 150b may include an upper chuck structure, a lower chuck structure, a push rod, etc. The upper chuck structure may suction and fix the first substrate via an upper stage. The lower chuck structure may suction and fix the second substrate via a lower stage. The push rod may pressurize the first substrate and/or the second substrate.

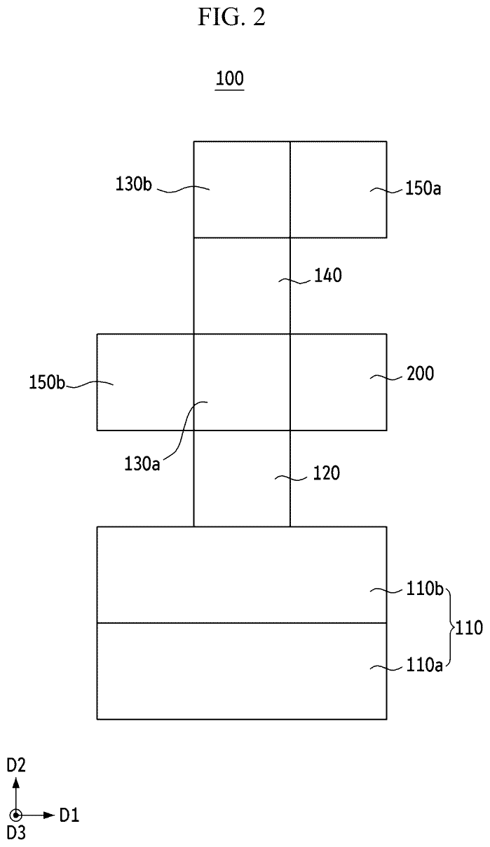

The buffer chamber 120 may be adjacent to the first transfer module 130a and spaced apart from the index module 110b. In this case, the first transfer module 130a may be adjacent to the index module 110b. For example, the buffer chamber 120 may be communicatively connected to the index module 110b via the first transfer module 130a. However, embodiments of the present disclosure are not limited thereto. Referring to FIG. 2, the buffer chamber 120 may be disposed between the first transfer module 130a and the index module 110b. The first transfer module 130a may be spaced apart from the index module 110b. For example, the first transfer module 130a may be communicatively connected to the index module 110b via the buffer chamber 120. FIG. 2 is a second example diagram for illustrating an internal structure of the substrate treating system according to some embodiments of the present disclosure.

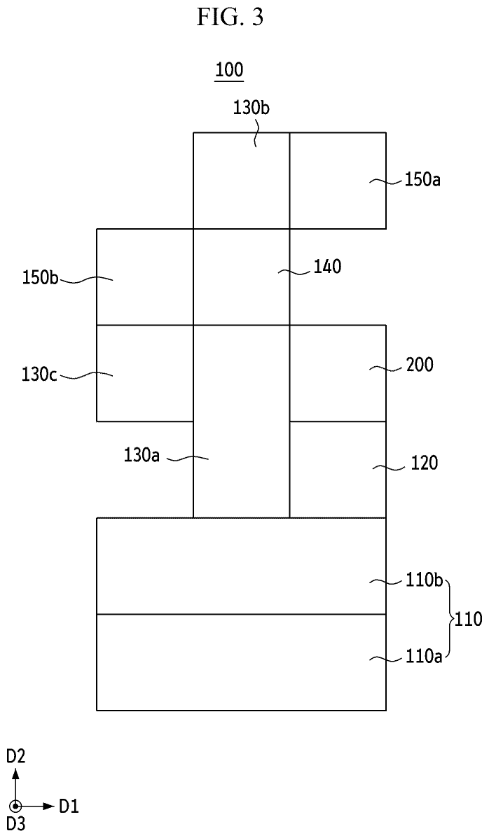

The substrate treating system 100 may further include a third transfer module 130c. FIG. 3 is a third example diagram for illustrating an internal structure of the substrate treating system according to some embodiments of the present disclosure.

The third transfer module 130c may be provided as an interface for transferring the substrate between the first transfer module 130a and the second process chamber 150b. Like the first transfer module 130a, the third transfer module 130c may include a transfer robot for loading and unloading the substrate. The transfer robot disposed within the first transfer module 130a and the transfer robot disposed within the third transfer module 130c may load and unload the substrate in the same environment. The transfer robot disposed within the third transfer module 130c may load or unload the substrate in an atmospheric pressure environment.

The transfer robot disposed in the third transfer module 130c may flip the substrate. The transfer robot disposed in the third transfer module 130c may include a cooling plate. The cooling plate may cool the first and second substrates before bonding the first and second substrates to each other. When the substrate treating system 100 does not include the third transfer module 130c, the transfer robot disposed in the first transfer module 130a may include the cooling plate.

A plurality of transfer robots may be provided within the third transfer module 130c. For example, a first substrate robot and a second substrate robot may be provided in the third transfer module 130c. When introducing the substrate into the second process chamber 150b, the first substrate robot may load the first substrate, and the second substrate robot may load the second substrate. Each of the first substrate robot and the second substrate robot may load a specified substrate. However, embodiments of the present disclosure are not limited thereto. The first substrate robot may load the substrate provided first among the first and second substrates, while the second substrate robot may load the substrate provided later among the first and second substrates. Each of the first substrate robot and the second substrate robot may load an unspecified substrate.

In one example, a single transfer robot may be provided within the third transfer module 130c. The example in FIG. 3 may be equally applied to the example in FIG. 2 as well as the example in FIG. 1. For example, the examples shown in FIG. 1 and/or FIG. 2 may include the third transfer module 130c.

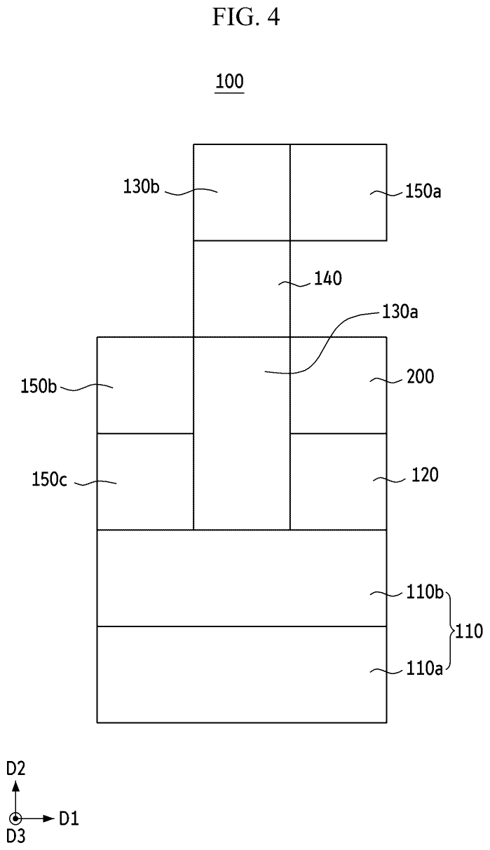

The substrate treating system 100 may further include a third process chamber 150c. FIG. 4 is a fourth example diagram for illustrating an internal structure of the substrate treating system according to some embodiments of the present disclosure.

The third process chamber 150c may inspect the substrate. After the first substrate and the second substrate have been bonded to each other by the second process chamber 150b, the third process chamber 150c may inspect the bonded substrates. The third process chamber 150c may inspect whether a bond state between the first substrate and the second substrate is good.

Like the second process chamber 150b, the third process chamber 150c may be disposed adjacent to the first transfer module 130a. The transfer robot disposed in the first transfer module 130a may provide the substrate treated by the second process chamber 150b to the third process chamber 150c.

In one example, the example in FIG. 4 may be applied equally to the example in FIG. 2 as well as the example in FIG. 1. Alternatively, the example in FIG. 4 may be equally applied to the example in FIG. 3. According to embodiments, the example in FIG. 4 may be equally applied to an example in which the third transfer module 130c is applied to the example in FIG. 2.

According to embodiments, the substrate treating system 100 may further include a control device. The control device may include a processor that controls each of components of the substrate treating system 100, a network that communicates, in a wired or wireless manner, with each of the components, one or more instruction related to functions or operations for controlling each of the components, and a memory for storing therein the one or more instructions, treating recipes, and various data. The control device may further include a user interface including an input means (e.g., an inputter) used for an operator to input commands to manage the substrate treating system 100, an output means (e.g., an outputter) for visualizing and displaying the operation status of the substrate treating system 100, etc. The control device may be a computing device for data processing and analysis, command transmission, etc.

The instructions may be provided in a form of a computer program or application. The computer program may include one or more instructions and be stored in a computer-readable recording medium (e.g., the memory). The instructions may include codes generated by a compiler, codes that may be executed by an interpreter, etc. The memory may be provided as one or more storage media selected from among, for example, flash memory, a hard disk drive (HDD), a solid-state drive (SSD), card type memory, random-access memory (RAM), static random-access memory (SRAM), read-only memory (ROM), electrically erasable programmable read-only memory (EEPROM), programmable read-only memory (PROM), magnetic memory, magnetic disk, and optical disk.

Referring to FIG. 1, the substrate cleaning apparatus 200 may clean the substrate. In this regard, the substrate may be either the first substrate or the second substrate. Alternatively, the substrate may include both the first substrate and the second substrate.

The substrate cleaning apparatus 200 may include a brush. The substrate cleaning apparatus 200 may remove foreign substances present on the surface of the substrate using the brush. For example, the foreign substance may be a particle. The substrate cleaning apparatus 200 may effectively remove the foreign substance stuck to the substrate with a strong force using the brush.

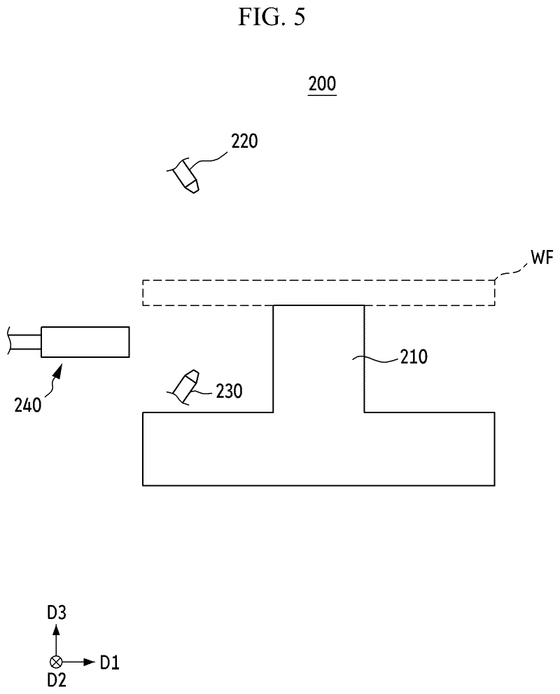

FIG. 5 is a first example diagram for illustrating an internal structure of a substrate cleaning apparatus according to some embodiments of the present disclosure. Referring to FIG. 5, the substrate cleaning apparatus 200 may include a substrate support 210, a first liquid supply 220, a second liquid supply 230, and a foreign substance remover 240.

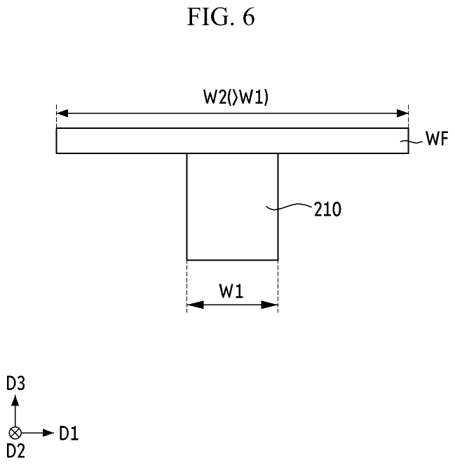

The substrate support 210 may support a substrate WF. The substrate support 210 may support the substrate WF while the substrate WF is being cleaned. Referring to FIG. 6, a width W1 of the substrate support 210 may be smaller than a width W2 of the substrate WF (W1<W2). The substrate support 210 may support a center portion of the substrate WF. FIG. 6 is a first example diagram for illustrating the substrate support of the substrate cleaning apparatus according to some embodiments of the present disclosure.

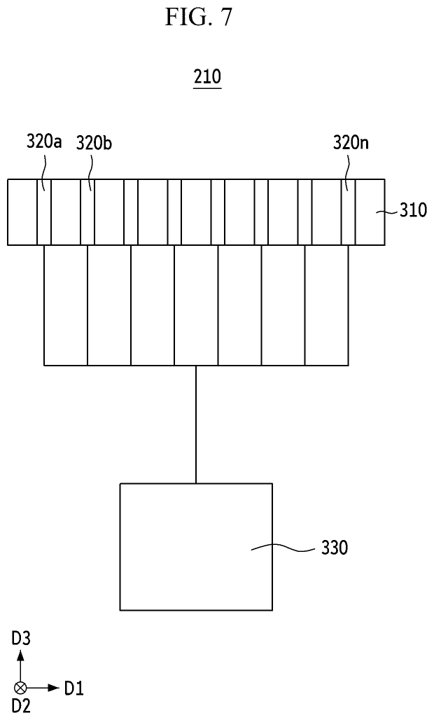

The substrate support 210 may suction the substrate WF. The substrate support 210 may suction the substrate WF when the substrate WF is seated on top thereof. The substrate support 210 may suction the substrate WF while the substrate cleaning apparatus 200 is cleaning the substrate WF. The substrate support 210 may be a vacuum chuck. Referring to FIG. 7, the substrate support 210 may include a plurality of holes 320a, 320b, . . . , 320n passing through a body 310 in the vertical direction D3. Each of the holes 320a, 320b, . . . , 320n may generate a vacuum state. The substrate cleaning apparatus 200 may further include a vacuum generator 330 for bringing each of the holes 320a, 320b, . . . , 320n into a vacuum state. For example, the vacuum generator 330 may be a vacuum pump. FIG. 7 is a second example diagram for illustrating the substrate support of the substrate cleaning apparatus according to some embodiments of the present disclosure.

The substrate support 210 may rotate the substrate WF. The substrate support 210 may rotate the substrate WF while the substrate cleaning apparatus 200 is cleaning the substrate WF. The substrate support 210 may rotate the substrate WF after the substrate support 210 has suctioned the substrate WF. The substrate support 210 may be provided as a spin chuck. According to embodiments, the substrate cleaning apparatus 200 may further include a power source and a motor. The power source may provide electrical energy to the motor. The motor may convert electrical energy into kinetic energy to rotate a shaft. The body 310 and the substrate WF on top thereof may rotate in conjunction with the shaft.

With reference to FIG. 5, the first liquid supply 220 and the second liquid supply 230 may provide liquid to the surface of the substrate WF. The first liquid supply 220 and the second liquid supply 230 may provide liquid to different surfaces of the substrate WF, respectively. For example, the first liquid supply 220 may provide liquid to an upper surface of the substrate WF, and the second liquid supply 230 may provide liquid to a lower surface of the substrate WF.

The first liquid supply 220 and the second liquid supply 230 may provide the same type of liquid. For example, the first liquid supply 220 and the second liquid supply 230 may provide deionized water (DIW). However, embodiments of the present disclosure are not limited thereto, and the first liquid supply 220 and the second liquid supply 230 may also provide different types of liquids, respectively. For example, the first liquid supply 220 may provide a chemical and the second liquid supply 230 may provide deionized water. For example, the chemical may be isopropyl alcohol (IPA).

The substrate cleaning apparatus 200 may simultaneously clean the upper and lower surfaces of the substrate WF. In this case, the first liquid supply 220 and the second liquid supply 230 may provide liquid at the same time. The substrate cleaning apparatus 200 may sequentially clean the upper and lower surfaces of the substrate WF. In this case, the first liquid supply 220 and the second liquid supply 230 may sequentially provide liquid.

Each of the first liquid supply 220 and the second liquid supply 230 may be formed to have a length direction that is not parallel to a width direction D1 or D2 of the substrate WF. For example, each of the first liquid supply 220 and the second liquid supply 230 may be formed to have a length direction inclined with respect to the width direction D1 or D2 of the substrate WF. However, embodiments of the present disclosure are not limited thereto, and each of the first liquid supply 220 and the second liquid supply 230 may be formed to have the length direction as the vertical direction D3 perpendicular to the width direction D1 or D2 of the substrate WF. The first liquid supply 220 may have the same length direction as the length direction of the second liquid supply 230, or may have a different length direction from the length direction of the second liquid supply 230. According to embodiments, the length direction may be a central axis along which the first liquid supply 220 or the second liquid supply 230 outputs liquid.

The first liquid supply 220 and the second liquid supply 230 may provide liquid in the same discharge scheme. For example, the first liquid supply 220 and the second liquid supply 230 may provide liquid in a mist scheme. However, embodiments of the present disclosure are not limited thereto, and the first liquid supply 220 and the second liquid supply 230 may provide liquid in different discharge schemes, respectively. For example, the first liquid supply 220 may provide liquid in a dripping scheme, and the second liquid supply 230 may provide liquid in a mist scheme. A more detailed description of the mist scheme and the dripping scheme is provided later.

The foreign substance remover 240 may remove foreign substances adhered to the surface of the substrate WF. The foreign substance remover 240 may be disposed at a lower vertical level than a vertical level of the substrate WF. The foreign substance remover 240 may be disposed at the same vertical level as a vertical level of the substrate support 210. Alternatively, the foreign substance remover 240 may be disposed at a lower vertical level than the vertical level of the substrate support 210. The foreign substance remover 240 may remove the foreign substances from the lower surface of the substrate WF.

The substrate cleaning apparatus 200 may clean the first and second substrates before the second process chamber 150b bonds the first and second substrates to each other. The foreign substance remover 240 may remove the foreign substance from the surface of the first substrate before the first substrate and the second substrate are bonded to each other. Furthermore, the foreign substance remover 240 may remove the foreign substance from the surface of the second substrate before the first substrate and the second substrate are bonded to each other.

The foreign substance remover 240 may remove foreign substances from the surface of the substrate WF using the brush. The foreign substance remover 240 may remove foreign substances from one portion of the substrate WF. For example, the foreign substance remover 240 may remove the foreign substance from an edge area of the substrate WF. Generally, when bonding the first substrate and the second substrate to each other, a significant number of voids occurs in the edge area. In this embodiment, taking this into consideration, the foreign substance remover 240 may remove the foreign substance from the edge area of the substrate WF. However, embodiments of the present disclosure are not limited thereto, and the foreign substance remover 240 may remove the foreign substances from an entire area of the substrate WF.

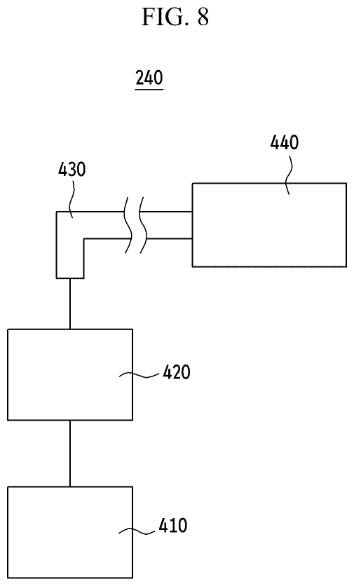

Referring to FIG. 8, the foreign substance remover 240 may include a power source 410, a motor 420, a shaft 430, and a brush 440. FIG. 8 is a first example diagram for illustrating a foreign substance remover of a substrate cleaning apparatus according to some embodiments of the present disclosure.

The power source 410 may provide electrical energy to the motor 420. The motor 420 may convert the electrical energy into kinetic energy to rotate the shaft 430. The shaft 430 may rotate clockwise. Alternatively, the shaft 430 may rotate counterclockwise. The brush 440 may be linked to the shaft 430 and rotate in the same direction as a rotation direction of the shaft 430. The brush 440 may perform a spin motion. The brush 440 may contact the surface of the substrate WF. The brush 440 may remove foreign substances from the surface of the substrate WF while rotating while in contact with the surface of the substrate WF. The brush 440 may be made of a resin-based material to avoid damaging the surface of the substrate WF when removing the foreign substance from the surface of the substrate WF. For example, the brush 440 may be made of poly-vinyl acetate (PVA) resin.

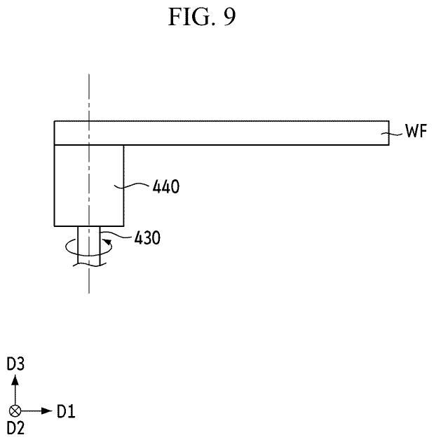

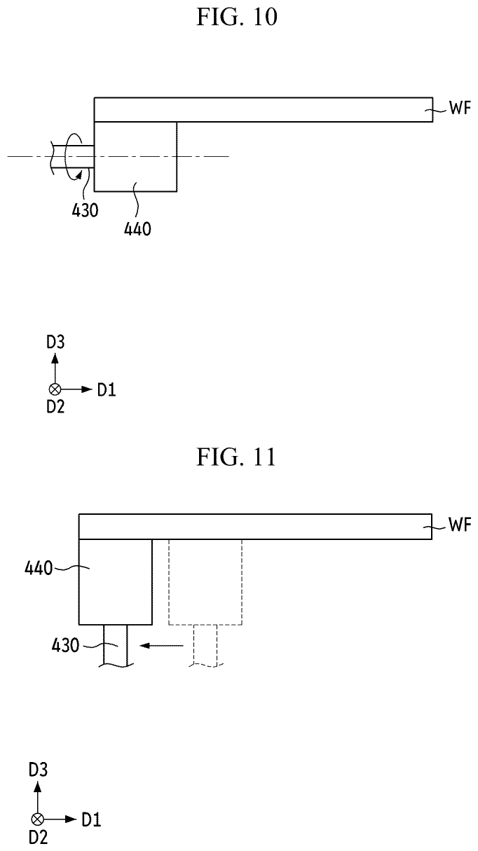

Referring to FIG. 9, the brush 440 may rotate clockwise or counterclockwise around a rotation axis extending in the direction D3 perpendicular to the width direction D1 or D2 of the substrate WF. However, embodiments of the present disclosure are not limited thereto. Referring to FIG. 10, the brush 440 may also rotate clockwise or counterclockwise around a rotation axis extending parallel to the width direction D1 or D2 of the substrate WF. The rotation axis of the brush 440 may be disposed under the body 310 of the substrate support 210 that suctions the substrate WF to shorten a brush movement. The rotation axis of the brush 440 may be constructed in a brush axis swivel structure. FIG. 9 is a second example diagram for illustrating a foreign substance remover of a substrate cleaning apparatus according to some embodiments of the present disclosure. FIG. 10 is a third example diagram for illustrating a foreign substance remover of a substrate cleaning apparatus according to some embodiments of the present disclosure.

The brush 440 may operate simultaneously with an operation of the second liquid supply 230. While the second liquid supply 230 provides liquid to the lower surface of the substrate WF, the brush 440 may contact the surface of the substrate WF and rotate. The liquid provided by the second liquid supply 230 may constitute a water film on the lower surface of the substrate WF. The water film may minimize direct contact between the substrate WF and the brush 440 when the brush 440 removes foreign substances. When the second liquid supply 230 and the brush 440 operate simultaneously with each other, damage to the lower surface of the substrate WF may be prevented.

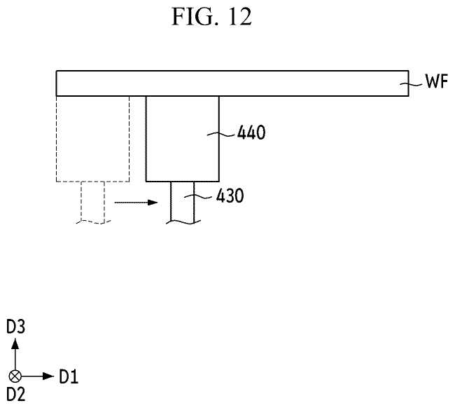

The brush 440 may rotate and, at the same time, move in a direction parallel to the width direction D1 or D2 of the substrate WF. The brush 440 may make a swing motion. Referring to FIG. 11, the brush 440 may move in an outward direction while rotating. The brush 440 may move in an outward direction while being in contact with the surface of the substrate WF. The brush 440 may move linearly in an outward direction. Alternatively, the brush 440 may move curvedly in an outward direction. Referring to FIG. 12, the brush 440 may move in an inward direction while rotating. The brush 440 may move in the inward direction while being in contact with the surface of the substrate WF. The brush 440 may move linearly in the inward direction. Alternatively, the brush 440 may move curvedly in the inward direction. Rotating and simultaneously moving the brush 440 in the horizontal direction may allow the entire area of the lower surface of the substrate WF to be uniformly cleaned. FIG. 11 is a fourth example diagram for illustrating a foreign substance remover of a substrate cleaning apparatus according to some embodiments of the present disclosure. FIG. 12 is a fifth example diagram for illustrating a foreign substance remover of a substrate cleaning apparatus according to some embodiments of the present disclosure.

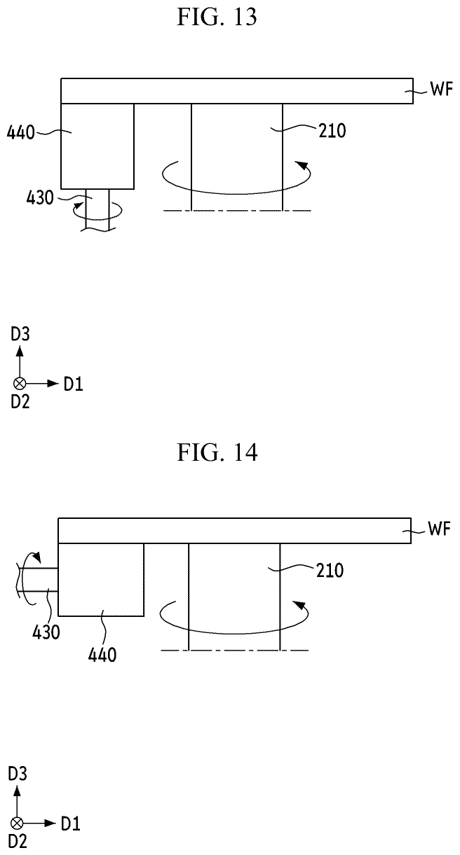

The foreign substance remover 240 may remove foreign substances while the substrate WF rotates. In this case, the rotation direction of the brush 440 may be opposite to the rotation direction of the substrate WF. Referring to FIG. 13, when the brush 440 has the vertical direction D3 as its rotation axis as shown in the example in FIG. 9, the substrate WF may rotate counterclockwise and the brush 440 may rotate clockwise. Alternatively, according to embodiments, the substrate WF may rotate clockwise and the brush 440 may rotate counterclockwise. Furthermore, referring to FIG. 14, when the brush 440 has the horizontal direction D1 or D2 as its rotation axis as shown in the example in FIG. 10, the substrate WF may rotate counterclockwise and the brush 440 may rotate clockwise. Alternatively, according to embodiments, the substrate WF may rotate clockwise and the brush 440 may rotate clockwise. In one example, when the brush 440 has the vertical direction D3 as its rotation axis, the rotation direction of the brush 440 may be the same as the rotation direction of the substrate WF. FIG. 13 is a sixth example diagram for illustrating a foreign substance remover of a substrate cleaning apparatus according to some embodiments of the present disclosure. FIG. 14 is a seventh example diagram for illustrating a foreign substance remover of a substrate cleaning apparatus according to some embodiments of the present disclosure.

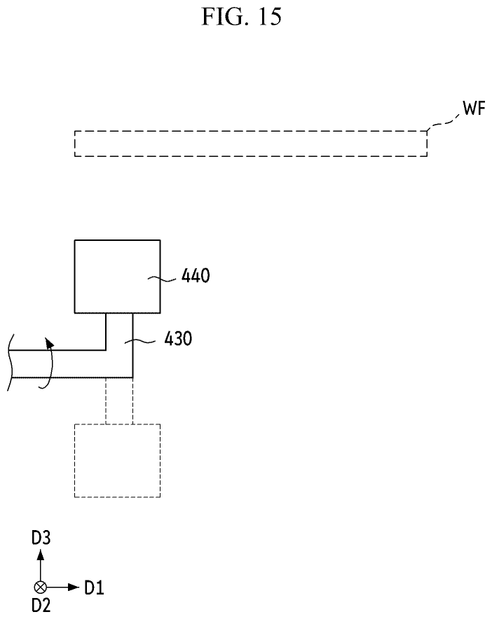

The brush 440 may perform a flip motion. Referring to FIG. 15, an upper surface of the brush 440 may not normally face the substrate WF. When cleaning of the substrate WF begins, the upper surface of the brush 440 may be turned to face the substrate WF in a flip motion. When cleaning of the substrate WF has been completed, the upper surface of the brush 440 may be turned again in a flip motion so that the upper surface does not face the substrate WF. The upper surface of the brush 440 may return to face in its original direction. FIG. 15 is an eighth example diagram for illustrating a foreign substance remover of a substrate cleaning apparatus according to some embodiments of the present disclosure.

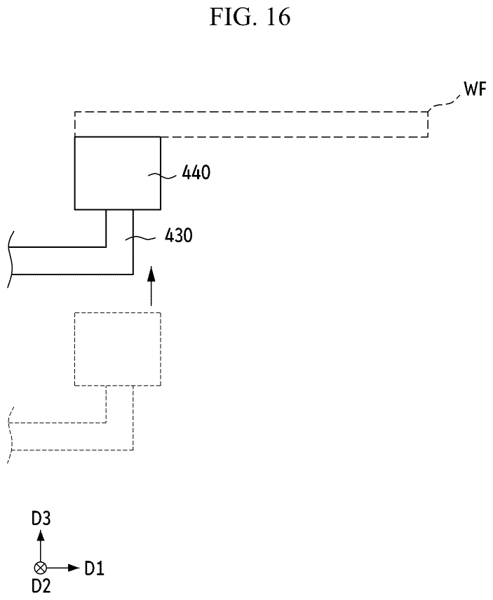

The brush 440 may perform an up/down motion. Referring to FIG. 16, normally, the brush 440 may be located at a vertical level at which the brush does not contact the lower surface of the substrate WF. When cleaning of the substrate WF begins, the brush 440 may move up to contact the lower surface of the substrate WF. When cleaning of the substrate WF has been completed, the brush 440 may descend so as to not contact the lower surface of the substrate WF again. The brush 440 may return to its original position. FIG. 16 is a ninth example diagram for illustrating a foreign substance remover of a substrate cleaning apparatus according to some embodiments of the present disclosure.

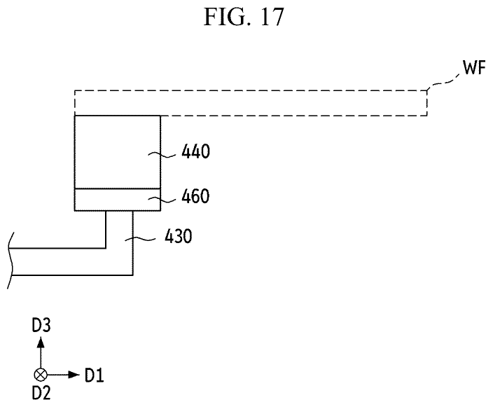

The foreign substance remover 240 may further include a contact force measurement sensor 460. Referring to FIG. 17, the contact force measurement sensor 460 may measure a contact force at which the brush 440 contacts the lower surface of the substrate WF. The foreign substance remover 240 may control a vertical motion of the brush 440 based on the measured value of the contact force measurement sensor 460. The foreign substance remover 240 may adjust the contact force at which the brush 440 contacts the lower surface of the substrate WF based on the measured value of the contact force measurement sensor 460. Using the contact force measurement sensor 460, the foreign substance remover 240 may prevent the brush 440 from damaging the substrate WF by pressing the substrate with the strong force.

The contact force measurement sensor 460 may be installed on the shaft 430. The contact force measurement sensor 460 may be disposed under the brush 440 to measure a load. For example, the contact force measurement sensor 460 may be a load cell. FIG. 17 is a tenth example diagram for illustrating a foreign substance remover of a substrate cleaning apparatus according to some embodiments of the present disclosure.

When cleaning both the upper and lower surfaces of the substrate WF, the first liquid supply 220 may be used to clean the upper surface of the substrate WF, and the second liquid supply 230 and the foreign substance remover 240 may be used to clean the lower surface of the substrate WF. That is, the foreign substance remover 240 may only be used to clean the lower surface of the substrate WF. However, embodiments of the present disclosure are not limited thereto. The foreign substance remover 240 may be used to clean not only the lower surface of the substrate WF but also the upper surface of the substrate WF. In this case, a plurality of the foreign substance remover 240 may be provided, and the foreign substance removers 240 may be respectively disposed at a higher vertical level and a lower vertical level than the vertical level of the substrate support 210. Alternatively, the foreign substance remover 240 disposed at the vertical level lower than the vertical level of the substrate support 210 may be used to clean the lower surface of the substrate WF and then may be used to clean the upper surface of the substrate WF.

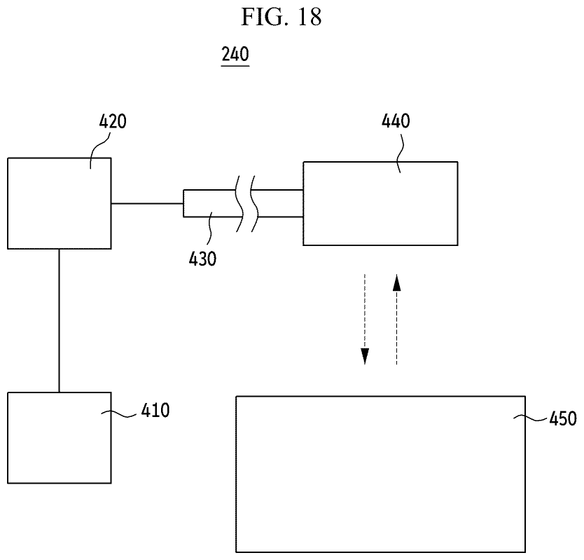

The foreign substance remover 240 may further include a drain cup 450. Referring to FIG. 18, the drain cup 450 may be disposed under the brush 440. Water may be stored in the drain cup 450. As described previously, the brush 440 may perform the flip motion and the vertical motion. The brush 440 may move into or out of the drain cup 450 normally (when cleaning the lower surface of the substrate WF), and may retain moisture stored in the drain cup 450. The brush 440 may minimize a friction with the surface of the substrate WF even when the water film is not normally formed on the lower surface of the substrate WF. Furthermore, the water stored in the drain cup 450 may wash the foreign substances suctioned to the brush 440. The water that has washed away the foreign substances from the brush 440 may be discharged to an outside, and new water may flow into the drain cup 450. FIG. 18 is an eleventh example diagram for illustrating a foreign substance remover of a substrate cleaning apparatus according to some embodiments of the present disclosure.

The substrate cleaning apparatus 200 may continuously use the second liquid supply 230 and the foreign substance remover 240 while cleaning the lower surface of the substrate WF. However, embodiments of the present disclosure are not limited thereto. The substrate cleaning apparatus 200 may simultaneously use the second liquid supply 230 and the foreign substance remover 240 during one partial period, and may use only the second liquid supply 230 during another partial period. Alternatively, while cleaning the lower surface of the substrate WF, simultaneous use of the second liquid supply 230 and the foreign substance remover 240 and use of only the second liquid supply 230 may be repeated.

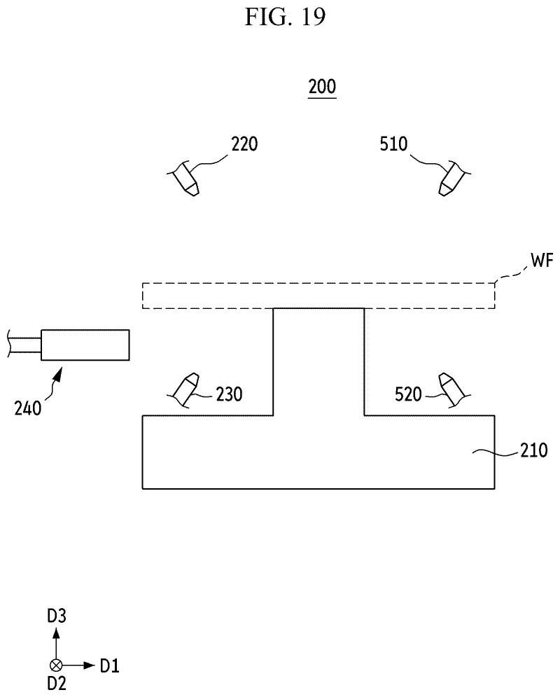

With reference to FIG. 19, the substrate cleaning apparatus 200 may further include a first gas supply 510 and a second gas supply 520. FIG. 19 is a second example diagram for illustrating the internal structure of a substrate cleaning apparatus according to some embodiments of the present disclosure.

The first gas supply 510 and the second gas supply 520 may provide gas to the surface of the substrate WF. The first gas supply 510 and the second gas supply 520 may provide gas to different surfaces of the substrate WF, respectively. For example, the first gas supply 510 may provide gas to the upper surface of the substrate WF, and the second gas supply 520 may provide gas to the lower surface of the substrate WF.

The substrate cleaning apparatus 200 may perform a drying process after the cleaning process. When performing the cleaning process, the substrate cleaning apparatus 200 may use the first liquid supply 220, the second liquid supply 230, and the foreign substance remover 240. The substrate cleaning apparatus 200 may remove foreign substances from the surface of the substrate WF through the cleaning process. When performing the drying process, the substrate cleaning apparatus 200 may use the first gas supply 510 and the second gas supply 520. The substrate cleaning apparatus 200 may remove moisture from the surface of the substrate WF through the drying process.

The first gas supply 510 and the second gas supply 520 may provide the same type of gas. For example, the first gas supply 510 and the second gas supply 520 may provide nitrogen N₂ gas. However, embodiments of the present disclosure are not limited thereto, and the first gas supply 510 and the second gas supply 520 may also provide different types of gas, respectively. The first gas supply 510 may provide a first gas, and the second gas supply 520 may provide a second gas. The first gas and the second gas may not react with each other and may be suitable gases for removing the moisture from the surface of the substrate WF.

The substrate cleaning apparatus 200 may simultaneously dry the upper and lower surfaces of the substrate WF. In this case, the first gas supply 510 and the second gas supply 520 may provide gas at the same time. The substrate cleaning apparatus 200 may sequentially dry the upper and lower surfaces of the substrate WF. In this case, the first gas supply 510 and the second gas supply 520 may sequentially provide the gas. Each of the first gas supply 510 and the second gas supply 520 may be formed to have a length direction that is not parallel to the width direction D1 or D2 of the substrate WF. For example, each of the first gas supply 510 and the second gas supply 520 may be formed to have a length direction inclined with respect to the width direction D1 or D2 of the substrate WF. However, embodiments of the present disclosure are not limited thereto, and each of the first gas supply 510 and the second gas supply 520 may also be formed to have a length direction (e.g., the direction D3) perpendicular to the width direction D1 or D2 of the substrate WF. The first gas supply 510 may have the same length direction as a length direction of the second gas supply 520, or may have a different length direction from the length direction of the second gas supply 520. According to embodiments, the length direction may be a central axis along which the first gas supply 510 or the second gas supply 520 outputs gas.

According to embodiments, the substrate cleaning apparatus 200 may include the first gas supply 510 and may not include the second gas supply 520. When the substrate cleaning apparatus 200 performs the drying process, the upper surface of the substrate WF may be dried by the gas provided from the first gas supply 510, and the lower surface of the substrate WF may be naturally dried. Alternatively, the substrate cleaning apparatus 200 may include the second gas supply 520 and may not include the first gas supply 510. When the substrate cleaning apparatus 200 performs the drying process, the upper surface of the substrate WF may be naturally dried, and the lower surface of the substrate WF may be dried by gas provided from the second gas supply 520.

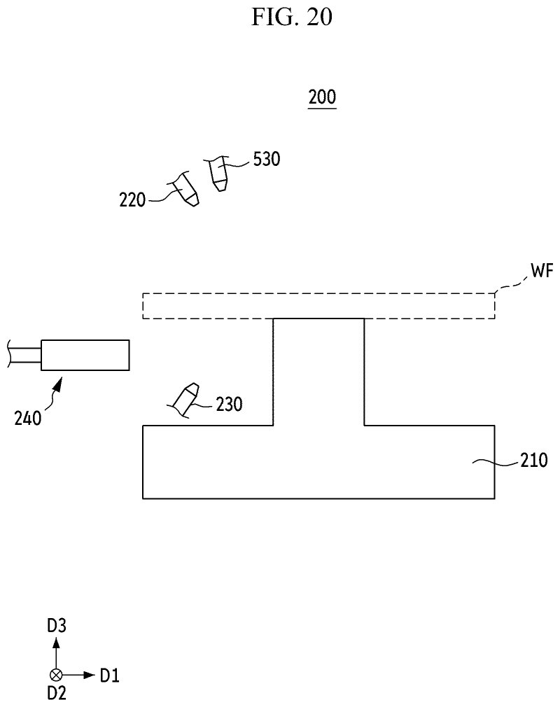

With reference to FIG. 20, the substrate cleaning apparatus 200 may further include a third liquid supply 530. FIG. 20 is a third example diagram for illustrating an internal structure of a substrate cleaning apparatus according to some embodiments of the present disclosure.

Like the first liquid supply 220, the third liquid supply 530 may provide liquid to the upper surface of the substrate WF. The first liquid supply 220 may provide first liquid, and the third liquid supply 530 may provide second liquid. Each of the first liquid supply 220 and the third liquid supply 530 may be disposed at a vertical level higher than a vertical level of the substrate WF. The first liquid and the second liquid may be different liquids from each other. For example, the first liquid may be a chemical, and the second liquid may be deionized water. For example, the chemical may be isopropyl alcohol.

The first liquid supply 220 and the third liquid supply 530 may provide liquid when cleaning the upper surface of the substrate WF. The first liquid supply 220 and the third liquid supply 530 may provide liquid at the same time. However, embodiments of the present disclosure are not limited thereto, and only one liquid supply among the first liquid supply 220 and the third liquid supply 530 may provide the liquid.

According to embodiments, the substrate cleaning apparatus 200 may further include at least one gas supply among the first gas supply 510 and the second gas supply 520 as well as the third liquid supply 530.

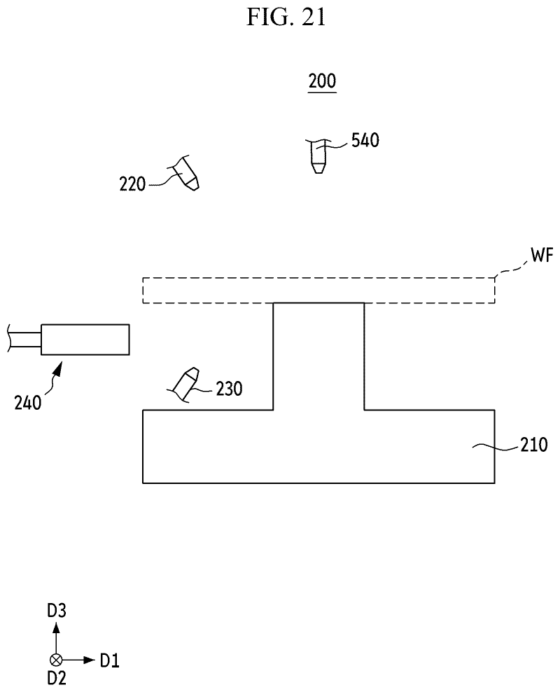

With reference to FIG. 21, the substrate cleaning apparatus 200 may further include a fourth liquid supply 540. FIG. 21 is a fourth example diagram for illustrating an internal structure of a substrate cleaning apparatus according to some embodiments of the present disclosure.

Like the first liquid supply 220, the fourth liquid supply 540 may provide liquid to the upper surface of the substrate WF. The first liquid supply 220 and the fourth liquid supply 540 may provide the same type of liquid. For example, the first liquid supply 220 and the fourth liquid supply 540 may provide deionized water.

The fourth liquid supply 540 may provide liquid at a different time from a time at which the first liquid supply 220 provides liquid. A period for which cleaning of the substrate WF is performed may be divided into a first period and a second period. The first liquid supply 220 may provide liquid during the first period as a first half period, and the fourth liquid supply 540 may provide liquid during the second period as a second half period.

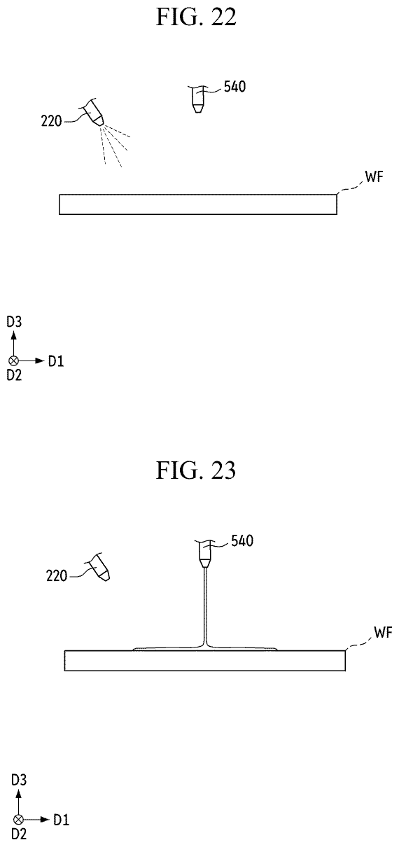

The fourth liquid supply 540 may provide liquid in a discharge scheme different from a scheme in which the first liquid supply 220 discharges liquid. Referring to FIG. 22, the first liquid supply 220 may provide liquid in a mist scheme. Referring to FIG. 23, the fourth liquid supply 540 may provide liquid in a dripping scheme. In this regard, the dripping scheme refers to a scheme of continuously discharging liquid droplets of a certain size to a narrow range of destinations. The mist scheme refers to a scheme of spraying fine sized liquid droplets (i.e., liquid droplets of a size smaller than a size of the droplets in the dripping scheme) to a wide range of destinations. The first liquid supply 220 may be provided as an aerosol nozzle. FIG. 22 is a first example diagram for illustrating a liquid supply of a substrate cleaning apparatus according to some embodiments of the present disclosure. FIG. 23 is a second example diagram for illustrating a liquid supply of a substrate cleaning apparatus according to some embodiments of the present disclosure.

According to embodiments, the substrate cleaning apparatus 200 may further include at least one gas supply among the first gas supply 510 and the second gas supply 520 in addition to the fourth liquid supply 540. Alternatively, the substrate cleaning apparatus 200 may further include a third liquid supply 530 in addition to the fourth liquid supply 540. Alternatively, the substrate cleaning apparatus 200 may further include at least one gas supply among the first gas supply 510 and the second gas supply 520 and the third liquid supply 530 along with the fourth liquid supply 540.

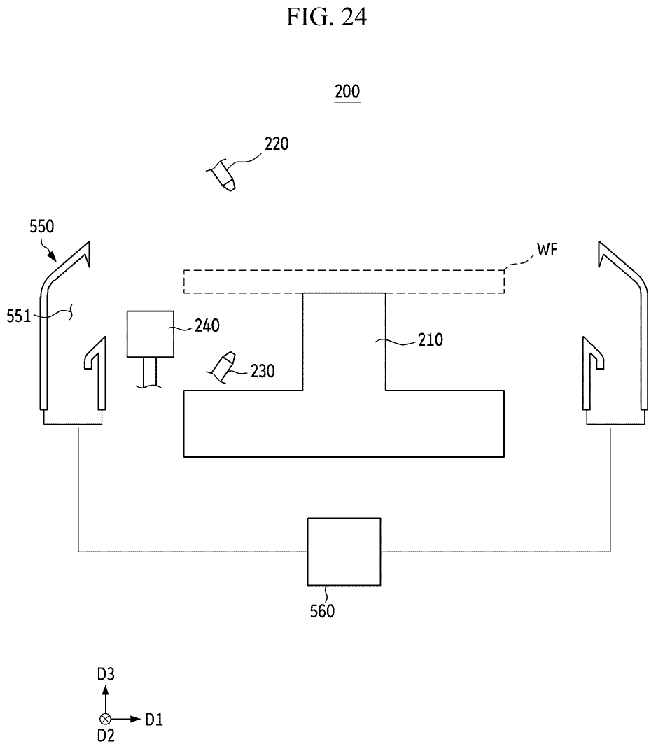

With reference to FIG. 24, the substrate cleaning apparatus 200 may further include a collector 550 and a vertically-moving means 560. FIG. 24 is a fifth example diagram for illustrating an internal structure of a substrate cleaning apparatus according to some embodiments of the present disclosure.

The collector 550 may be provided to surround the substrate support 210 and the substrate WF mounted on top thereof. The collector 550 may collect the liquid used to clean the substrate WF. While the substrate WF is fixed on the substrate support 210, the substrate support 210 rotates. At this time, the first liquid supply 220 may discharge liquid on the substrate WF. The liquid discharged on the substrate WF may be splashed toward the collector 550 due to the centrifugal force generated by the rotation of the substrate support 210. The collector 550 may collect the liquid dispersed in all directions through an inlet 551. The collector 550 may be provided as a bowl.

The vertically-moving means 560 may vertically move the collector 550. The vertically-moving means 560 may adjust a vertical level of each of the collector 550 and the inlet 551 so that liquid dispersed in all directions may flow into the inlet 551 of the collector 550. The vertically-moving means 560 may appropriately adjust the vertical level of each of the collector 550 and the inlet 551 in consideration of a vertical distance therefrom to the substrate WF and an angle at which the liquid is splashed from the substrate WF. The vertically-moving means 560 may vertically move the substrate support 210 without vertically moving the collector 550. Alternatively, the vertically-moving means 560 may vertically move one or more (e.g., some or all) of the collector 550, the inlet 551, and the substrate support 210.

According to embodiments of the present disclosure, the vertically-moving means 560 may include at least one actuator to move one or both of the collector 550 and the substrate support 210.

When the first liquid supply 220 and the second liquid supply 230 provide different liquids, respectively, the collector 550 may be provided as two collection ducts. Similarly, even when the first liquid supply 220 and the third liquid supply 530 provide different liquids, respectively, the collector 550 may be provided as two collection ducts.

Each of a first collection duct and a second collection duct, among the two collection ducts, may be provided in an annular ring shape. The first collection duct may be installed to surround the substrate support 210. The other of the two collection ducts, that is, the second collection duct may be installed to surround the first collection duct. The collector 550 may be configured such that different collection ducts collect different liquids, respectively such that reuse of each of the liquids may be realized.

When cleaning the lower surface of the substrate WF, the foreign substances may be removed from the lower surface of the substrate WF using a chemical reaction caused by a chemical solution and a physical rotational force acting on the substrate WF. However, in this approach, a cleaning power on the center portion of the substrate WF and a cleaning power on the edge portion of the substrate WF may be different from each other. Thus, this approach, in a comparative embodiment, has limitations in removing the foreign substances that are strongly attached to the surface of the substrate WF.

In accordance with some example embodiments of the present disclosure, the foreign substance remover 240 including the brush 440 may be used such that the foreign substances adhered to the lower surface of the substrate WF with a strong force may be completely removed, and the entire area of the substrate WF may be cleaned evenly.

According to some example embodiments of the present disclosure, the substrate treating system 100 may further include a controller configured to cause the substrate treating system 100 to perform its functions. For example, the controller may be configured to cause components (e.g., the EFEM 110, the buffer chamber 120, the substrate cleaning apparatus 200, transfer modules, the load lock chamber 140, and/or process chambers) of the substrate treating system 100 to perform their respective functions.

According to some example embodiments of the present disclosure, the controller may be completely or partially within one or more (e.g., some or all) of the components (e.g., the EFEM 110, the buffer chamber 120, the substrate cleaning apparatus 200, transfer modules, the load lock chamber 140, and/or process chambers).

According to some example embodiments of the present disclosure, the controller may include at least one processor and memory storing computer instructions. The computer instructions may be configured to, when executed by the at least one processor, cause the controller to perform its functions.

Although non-limiting example embodiments of the present disclosure have been described with reference to the accompanying drawings, embodiments of the present disclosure are not limited to the example embodiments, and may be implemented in various different forms. Embodiments of the present disclosure may be practiced in other concrete forms without departing from the spirit and scope of the present disclosure. Therefore, it should be appreciated that the example embodiments as described above are not restrictive and are illustrative in all respects.

What is claimed is:

1. A substrate treatment system comprising:
a first process chamber configured to plasma-treat a first substrate and a second substrate;
a substrate cleaning apparatus configured to clean the first substrate and the second substrate; and
a second process chamber configured to bond the first substrate and the second substrate to each other,
wherein the substrate cleaning apparatus is further configured to remove, using a cleaning liquid and a brush, a foreign substance adhered to the first substrate and the second substrate, and
wherein the second process chamber is further configured to bond the first substrate and the second substrate to each other after the first substrate and the second substrate are cleaned by the substrate cleaning apparatus.

2. The substrate treatment system of claim 1, wherein the substrate cleaning apparatus comprises:
a substrate support configured to support the first substrate;
a first liquid supply configured to provide a first liquid to a first surface of the first substrate;
a second liquid supply configured to provide a second liquid to a second surface of the first substrate; and
a foreign substance remover configured to remove the foreign substance from the second surface by contacting the second surface.

3. The substrate treatment system of claim 2, wherein the foreign substance remover is further configured to rotate while being in contact with the second surface.

4. The substrate treatment system of claim 3, wherein the foreign substance remover is further configured to rotate around a rotation axis extending in a direction perpendicular or parallel to a width direction of the first substrate.

5. The substrate treatment system of claim 3, wherein the substrate support is further configured to rotate the first substrate.

6. The substrate treatment system of claim 5, wherein a rotation direction of the foreign substance remover is different from a rotation direction of the substrate support.

7. The substrate treatment system of claim 2, wherein the foreign substance remover is further configured to move inwardly or outwardly of the first substrate while being in contact with the second surface.

8. The substrate treatment system of claim 2, further comprising a controller, wherein the controller is configured to control the foreign substance remover and the second liquid supply to operate simultaneously.

9. The substrate treatment system of claim 2, further comprising a controller,
wherein the controller is configured to control the foreign substance remover to flip based on whether a cleaning by the substrate cleaning apparatus is in progress.

10. The substrate treatment system of claim 2, further comprising a controller, wherein the controller is configured to control the foreign substance remover to move vertically based on whether a cleaning by the substrate cleaning apparatus is in progress.

11. The substrate treatment system of claim 2, wherein a width of the substrate support is smaller than a width of the first substrate.

12. The substrate treatment system of claim 11, wherein the substrate support is further configured to vacuum-suction the first substrate.

13. The substrate treatment system of claim 2, wherein the first liquid is a chemical or deionized water, and the second liquid is deionized water.

14. The substrate treatment system of claim 2, wherein the substrate cleaning apparatus further comprises:
the brush, wherein the brush is configured to contact the second surface; and
a drain cup under the brush and configured to contain the second liquid,
wherein the brush is configured to contact the second surface while the drain cup retains the second liquid.

15. The substrate treatment system of claim 2, wherein the substrate cleaning apparatus further comprises:
a gas supply configured to provide a gas to the second surface; and
a controller, and
wherein the controller is configured to:
control the foreign substance remover to move vertically based on whether a cleaning by the substrate cleaning apparatus is in progress; and
control the gas supply to provide the gas based on an operation of each of the second liquid supply and the foreign substance remover being terminated.

16. The substrate treatment system of claim 2, wherein the substrate cleaning apparatus further comprises a third liquid supply configured to provide a third liquid to the first surface, and
wherein the first liquid and the third liquid are different from each other.

17. The substrate treatment system of claim 2, wherein the substrate cleaning apparatus further comprises a fourth liquid supply configured to provide a fourth liquid to the first surface, and
wherein the first liquid supply and the fourth liquid supply have different discharge times and discharge schemes from each other.

18. The substrate treatment system of claim 2, wherein the substrate cleaning apparatus further comprises a collector around the substrate support, and
wherein the collector is configured to collect the first liquid or the second liquid in a recyclable manner.

19. A substrate cleaning apparatus comprising:
a substrate support configured to support a substrate;
a first liquid supply configured to provide a first liquid to a first surface of the substrate;
a second liquid supply configured to provide a second liquid to a second surface of the substrate; and
a foreign substance remover configured to: remove a foreign substance from the second surface by contacting the second surface,
wherein the foreign substance remover is further configured to remove the foreign substance using the second liquid and a brush,
wherein the foreign substance remover is further configured to rotate while being in contact with the second surface, and
wherein the foreign substance remover is further configured to flip or vertically move based on whether a cleaning by the substrate cleaning apparatus is in progress.

20. A substrate treatment system comprising:
a first process chamber configured to etch a first substrate and a second substrate;
a substrate cleaning apparatus configured to clean the first substrate and the second substrate and to remove, using a cleaning liquid and a brush, a foreign substance adhered to the first substrate and the second substrate; and
a second process chamber configured to bond the first substrate and the second substrate to each other,
wherein the substrate cleaning apparatus comprises:
a substrate support configured to support the first substrate;
a first liquid supply configured to provide a first liquid to a first surface of the first substrate;
a second liquid supply configured to provide a second liquid to a second surface of the first substrate; and
a foreign substance remover configured to remove the foreign substance from the second surface by contacting the second surface,
wherein the foreign substance remover is further configured to rotate while being in contact with the second surface,
wherein the foreign substance remover is further configured to move inwardly or outwardly of the first substrate while being in contact with the second surface,
wherein the foreign substance remover is further configured to flip or vertically move based on whether a cleaning by the substrate cleaning apparatus is in progress,
wherein the foreign substance remover and the second liquid supply are configured to operate simultaneously, and
wherein the second process chamber is further configured to bond the first substrate and the second substrate after the first substrate and the second substrate are cleaned by the substrate cleaning apparatus.
